(19) United States
(12) Patent Application Publication
(10) Pub. No.: US 2010/0032649 A1
(43) Pub. Date: Feb. 11, 2010

(54) LIGHT EMITTING DEVICE AND REDUCED POLARIZATION INTERLAYER THEREOF

(75) Inventors: WEN YU LIN, TAICHUNG COUNTY (TW); SHIH CHENG HUANG, HSINCHU CITY (TW); PO MIN TU, CHIAYI COUNTY (TW); YING CHAO YEH, TAIPEI COUNTY (TW); PENG YI WU, TAICHUNG CITY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/536,282

(22) Filed: Aug. 5, 2009

(30) Foreign Application Priority Data
Aug. 11, 2008 (TW) 097130611

(51) Int. Cl. H01L 33/00

(52) U.S. Cl. 257/13; 257/E33.008; 257/E33.023

(57) ABSTRACT

A light emitting device (LED), in which a reduced polarization interlayer is formed between an electron blocking layer (EBL) and an active layer of the LED, is disclosed. The reduced polarization interlayer is made of AlₓIn_{y}Ga_{1-x-y}N, where 0≦x≦1 and 0≦y≦1.

### BACKGROUND OF THE INVENTION

1. Field of the Invention

The present invention relates to a light emitting device.

2. Description of the Related Art

Referring to FIG. 1A, Japanese Patent Application No. JP2003-115642 discloses a structure of a traditional nitride semiconductor light emitting device having an electron blocking layer (EBL), wherein the light emitting device comprises an n-type conductive layer 11, an active layer 12, a p-type conductive layer 13, and an electron blocking layer 28; and wherein the electron blocking layer 28 is between the active layer 12 and the p-type conductive layer 13, and the active layer 12 is on the n-type conductive layer 11. The active layer 12 is of a structure, formed by alternatively stacking a plurality of quantum well layers (1a and 1b) and a plurality of quantum barrier layers (2a, 2b and 2c), in which the electron blocking layer 28 can confine the electrons from the n-type conductive layer 11 within the active layer 12. However, an electron blocking layer 28 is needed between the active layer 12 and the p-type conductive layer 13 due to the fact that the mobility of electrons in a nitride semiconductor element is larger than the mobility of holes. Thus, electrons easily overflow through the active layer 12.

FIG. 1B shows an energy band diagram of a traditional nitride semiconductor light emitting device. It can be seen that, compared to the active layer 12 or to the p-type conductive layer 13 of the above-described nitride semiconductor light emitting device, the electron blocking layer 28 clearly has higher energy band gap and so can stop the migration of electrons.

However, the electron blocking layer 28 and the active layer 12 in a traditional nitride semiconductor light emitting device are not lattice matched, so the piezoelectric polarization is occurred, the band gap is titled and the possibility of carriers overflow is increased in the active layer 12.

### SUMMARY OF THE INVENTION

According to the description in the Description of the Related Art and to meet the requirements and interests of the related industry, the present invention provides a light emitting device having none of the above-mentioned drawbacks of a traditional light emitting device.

One objective of the present invention is to provide a light emitting device, which comprises a substrate, a first conductive layer, an active layer, a reduced polarization interlayer, an electron blocking layer, and a second conductive layer. In the light emitting device, the first conductive layer is formed on the substrate, the active layer is on the first conductive layer, the reduced polarization interlayer is on the active layer, the electron blocking layer is on the reduced polarization interlayer, and the second conductive layer is on the electron blocking layer. The reduced polarization interlayer is made of AlₓIn_{y}Ga_{1-x-y}N, where 0≦x≦1 and 0≦y≦1.

To better understand the above-described objectives, characteristics and advantages of the present invention, embodiments, with reference to the drawings, are provided for detailed explanation.

### BRIEF DESCRIPTION OF THE DRAWINGS

The invention will be described according to the appended drawings in which:

FIG. 1A shows a structure of a traditional nitride semiconductor light emitting device;

FIGS. 1B and 3B show electron energy diagrams of a traditional nitride semiconductor light emitting device;

FIG. 2 shows the structure of a light emitting device according to one embodiment of the present invention;

FIG. 3A shows an electron energy diagram of a light emitting device without a reduced polarization interlayer according to one embodiment of the present invention;

FIG. 3B shows an electron energy diagram of a light emitting device having a reduced polarization interlayer according to one embodiment of the present invention; and

FIG. 3C shows a comparison of electron energies between the light emitting device of FIG. 3B and the light emitting device of FIG. 3A.

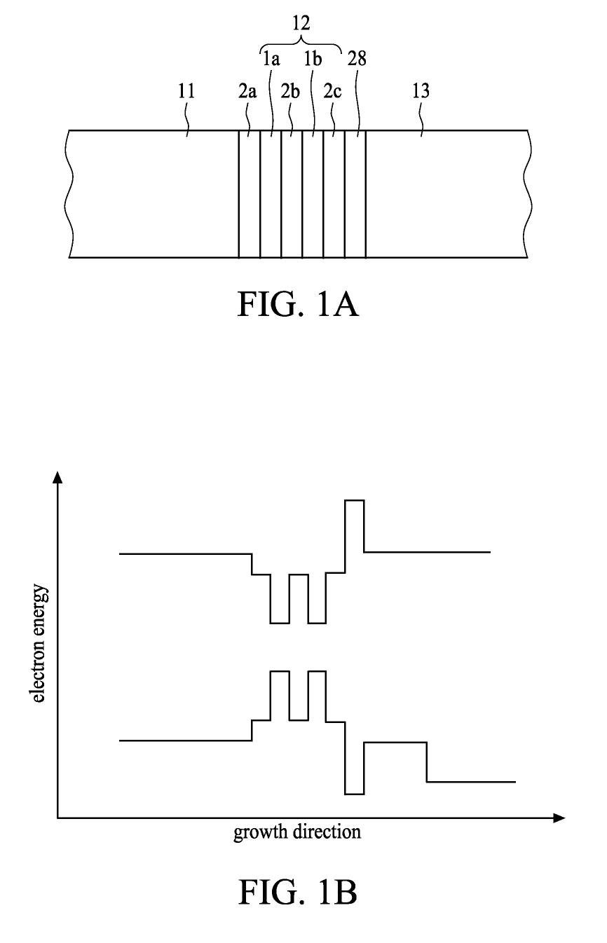

### DETAILED DESCRIPTION OF THE INVENTION

One aspect of the present invention suggests a light emitting device. In order to thoroughly understand the present invention, detailed descriptions of method steps and components are provided below. The implementations of the present invention are not limited to the specific details that are familiar to persons in the art related to a light emitting device. On the other hand, components or method steps which are well known are not described in detail. A preferred embodiment of the present invention is described in detail as follows. However, in addition to the preferred detailed description, other embodiments can be broadly employed, and the scope of the present invention is not limited by any of the embodiments, but should be defined in accordance with the following claims and their equivalent.

To lower the possibilities of carrier overflow in a light emitting device, U.S. Pat. No. 7,067,838 discloses a light emitting device having a carrier block layer, wherein the carrier block layer comprises AlₚIn_{q}Ga_{1-p-q}N (0≦p≦0.5 and 0≦q≦0.1). However, the lattice mismatch between the carrier block layer and the semiconductor layer below the carrier block layer contributes to significant piezoelectric polarization.

Similarly, U.S. Pat. No. 6,693,307 uses aluminum gallium nitride material to form an overflow preventing layer as the above carrier block layer. However, the overflow preventing layer does not solve the issue of piezoelectric polarization occurring in a carrier blocking layer. Therefore, the carrier blocking efficiency is low due to the influence of the band tilt of the overflow preventing layer.

Moreover, U.S. Pat. No. 6,744,064 discloses a multi-quantum barrier formed on an active layer to address the issue of piezoelectric polarization. Although the multi-quantum barrier serves a strain-compensating function to eliminate the piezoelectric polarization effect, according to the theory of Fresnel loss, reducing light extraction efficiency due to a light emitted from the active layer reflected by multi-interfaces of multi-quantum barrier.

U.S. Pat. No. 7,115,908 proposes a semiconductor layer made of a quaternary alloy to replace with a traditional gallium nitride semiconductor layer for elimination of the piezoelectric polarization effect.

In addition, a paper by Kim, et al., titled “Origin of efficiency droop in GaN-based light-emitting diodes,” APPLIED PHYSICS LETTER 91, 184507, 2007, indicates that quaternary AlGaInN quantum barriers and EBL can be polarization matched to the quantum wells and GaN, respectively, to reduce carrier overflow.

Summarily, traditional light emitting devices have some issues such as lattice mismatch, piezoelectric polarization effect, and a low light extraction in multi-interfaces to be solved.

Therefore, the present invention discloses a reduced polarization interlayer, made of quaternary alloy matched to an electron blocking layer (EBL), formed between the electron blocking layer and an active layer of a light emitting device, thereby reducing the band tilt of EBL caused by piezoelectric polarization from lattice mismatch between the electron blocking layer and the active layer, and minimizing the possibility of carrier overflow. Thus, carriers are confined within the active layer so that the light extraction efficiency of the light emitting device is increased.

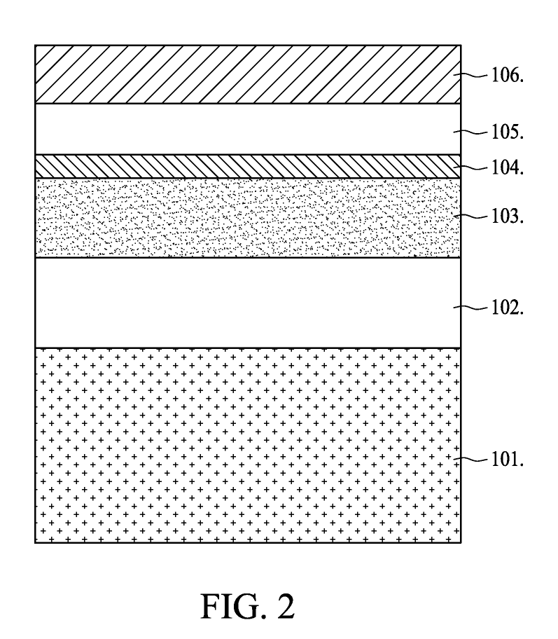

FIG. 2 shows the structure of a light emitting device according to one embodiment of the present invention. The light emitting device comprises a substrate 101, on which a first conductive layer 102, an active layer 103, a reduced polarization interlayer 104, an electron blocking layer (EBL) 105, and a second conductive layer 106 are sequentially formed, wherein the first conductive layer 102 can be an n-type conductive layer, and the second conductive layer can be a p-type conductive layer.

The reduced polarization interlayer 104, formed between the active layer 103 and the electron blocking layer 105, has the same lattice constant as the electron blocking layer 105. With such lattice match between the reduced polarization interlayer 104 and the electron blocking layer 105, the band tilt of EBL caused by the piezoelectric polarization due to lattice mismatch between the electron blocking layer 105 and the active layer 103 can be reduced, and the possibility of carrier overflow toward the second conductive layer 106 can be minimized.

Furthermore, a band gap of the electron blocking layer 105 is larger than those of the reduced polarization interlayer 104 and the active layer 103. In addition, the electron blocking layer 105 can be made of aluminum gallium nitride (AlGaN), and the reduced polarization interlay 104 can be made of AlₓIn_{y}Ga_{1-x-y}N, where 0≦x≦1 and 0≦y≦1. Also, the active layer 103 can be of a single quantum well structure or of a multiple quantum well structure.

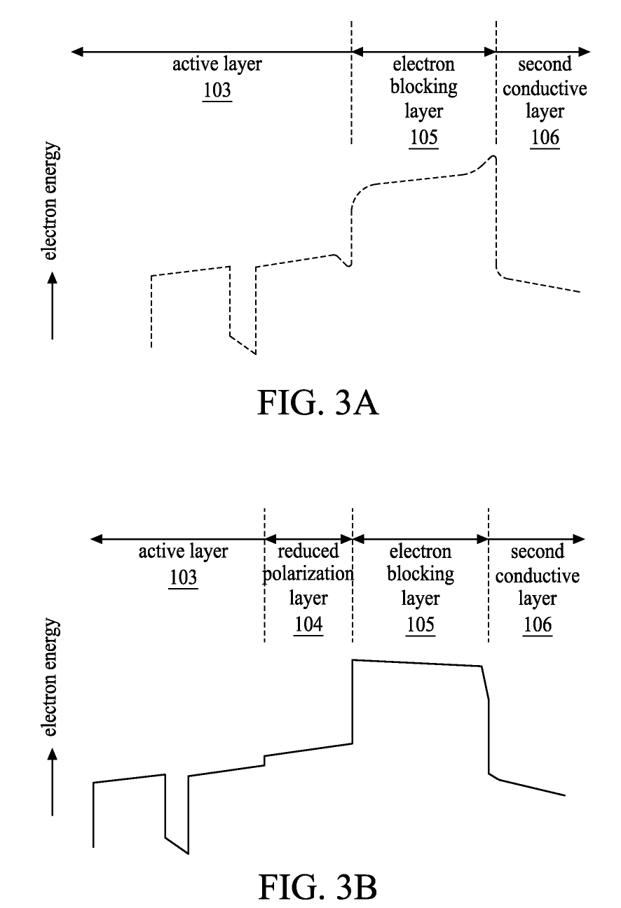

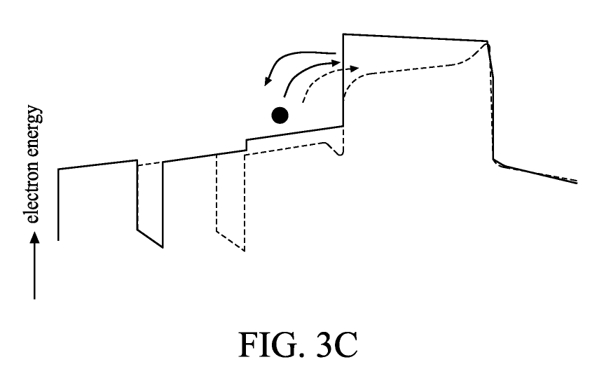

FIG. 3A shows an energy band diagram of a light emitting device without a reduced polarization interlayer 104 according to one embodiment of the present invention, wherein the dashed line represents the energy band profile of the light emitting device without a reduced polarization interlayer 104. Referring to FIG. 3A, the piezoelectric polarization due to the lattice mismatch between the electron blocking layer 105 and the active layer 103 causes band tilt of EBL such that the possibility of carrier overflow toward the second conductive layer 106 increased.

FIG. 3B shows an electron energy diagram of a light emitting device having a reduced polarization interlayer 104 according to one embodiment of the present invention, wherein the solid line represents the electron energy profile of the light emitting device having a reduced polarization interlayer 104; and FIG. 3C shows a comparison of electron energies between the light emitting device of FIG. 3B and the light emitting device of FIG. 3A. As shown in FIG. 3C, compared to the light emitting device having no reduced polarization layer 104 (dashed line), the band tilt of EBL in the light emitting device having a reduced polarization layer 104 (solid line) is significantly improved so that the possibility of carrier confined within the active layer 103 increases, and therefore, the light extraction efficiency of the light emitting device is improved.

Clearly, following the description of the above embodiments, the present invention may have many modifications and variations. Therefore, the scope of the present invention shall be considered with the scopes of the dependent claims. In addition to the above detailed description, the present invention can be broadly embodied in other embodiments. The above-described embodiments of the present invention are intended to be illustrative only, and should not become a limitation of the scope of the present invention. Numerous alternative embodiments may be devised by persons skilled in the art without departing from the scope of the following claims.

What is claimed is:

1. A light emitting device, comprising:
a substrate;
a first conductive layer formed on said substrate;
an active layer formed on said first conductive layer;
a reduced polarization interlayer formed on said active layer;
an electron blocking layer formed on said reduced polarization interlay, wherein said reduced polarization interlayer reduces the band tilt of electron blocking layer caused by piezoelectric polarization from the lattice mismatch between said electron blocking layer and said active layer, thereby minimizing the possibility of carrier overflow; and
a second conductive layer formed on said reduced polarization interlayer.

2. The light emitting device of claim 1, wherein a band gap of said electron blocking layer is larger than a band gap of said reduced polarization interlayer.

3. The light emitting device of claim 2, wherein a band gap of said electron blocking layer is larger than a band gap of said active layer.

4. The light emitting device of claim 2, wherein said reduced polarization interlayer is made of AlₓIn_{y}Ga_{1-x-y}N, wherein 0≦x≦1 and 0≦y≦1.

5. The light emitting device of claim 4, wherein said electron blocking layer is aluminum gallium nitride.

6. The light emitting device of claim 4, wherein said active layer is of a single quantum well structure or of a multiple quantum well structure.

7. The light emitting device of claim 6, wherein said first conductive layer is an n-type conductive layer.

8. The light emitting device of claim 7, wherein said second conductive layer is a p-type conductive layer.

9. A reduced polarization interlayer of a light emitting device, formed between an electron blocking layer and an active layer of said light emitting device to be lattice matched with said electron blocking layer.

10. The reduced polarization interlayer of the light emitting device of claim 9, wherein said reduced polarization interlayer is made of AlₓIn_{y}Ga_{1-x-y}N, where 0≦x≦1 and 0≦y≦1.

11. The reduced polarization interlayer of the light emitting device of claim 10, wherein said electron blocking layer is aluminum gallium nitride.

12. The reduced polarization interlayer of the light emitting device of claim 10, wherein said active layer is of a single quantum well structure or of a multiple quantum well structure.

13. A reduced polarization interlayer of a light emitting device, formed between an electron blocking layer and an active layer of said light emitting device, wherein the lattice constants of said reduced polarization interlayer and said electron blocking layer are the same.

14. The reduced polarization interlayer of the light emitting device of claim 13, wherein said reduced polarization interlayer is made of AlₓIn_{y}Ga_{1-x-y}N, where 0≦x≦1 and 0≦y≦1.

15. The reduced polarization interlayer of the light emitting device of claim 14, wherein the material of said electron blocking layer is aluminum gallium nitride.

16. The reduced polarization interlayer of the light emitting device of claim 15, wherein said active layer is of a single quantum well structure or of a multiple quantum well structure.
